(19) United States
(12) Patent Application Publication
(10) Pub. No.: US 2026/0191071 A1
(43) Pub. Date: Jul. 2, 2026

(54) METHOD FOR IMPROVING THE REFLOW SOLDERING YIELD OF A CHIP PACKAGE

(71) Applicant: JCET Management Co., Ltd., Shanghai (CN)

(72) Inventors: Jian CHENG, Shanghai (CN); Rao FU, Shanghai (CN); Jiabin LIU, Shanghai (CN); Yuqiang ZOU, Shanghai (CN); Liping ZHU, Shanghai (CN)

(73) Assignee: JCET Management Co., Ltd., Shanghai (CN)

(21) Appl. No.: 19/287,953

(22) Filed: Aug. 1, 2025

(30) Foreign Application Priority Data
Dec. 27, 2024 (CN) 201411950848.0

(51) Int. Cl. H01L 23/00

(52) U.S. Cl. CPC H10W 72/072; H10W 72/07231; H10W 72/07236; H10W 72/241

(57) ABSTRACT

A method for improving the reflow soldering yield of a chip package is provided. After establishing control rule 1 and control rule 2, step 5 is performed to determine whether the solder balls in the compression area of the initial package structure meet control rule 1 and whether the solder balls in the stretching area meet control rule 2. If both yes, then step 7 is directly performed. If no, step 6 is performed, optimization scheme 1 and optimization scheme 2 are respectively applied to optimize the initial design structure to make them meet control rule 1 and control rule 2; at step 7, actual production reflow soldering verification is performed, and a soldering quality yield check is performed; after step 7, step 8 is performed to determine whether the soldering quality yield meets the design requirements, if yes, then the process ends, if no, steps 6 and 7 are repeated, until the design requirements are met.

### CROSS-REFERENCE TO RELATED APPLICATIONS

This application claims the benefit of priority to Chinese Application No. 201411950848.0, filed on Dec. 27, 2024, which is hereby incorporated by reference in its entirety.

### TECHNICAL FIELD

The present disclosure relates to the technical field of semiconductor package, and particularly relates to a method for improving the reflow soldering yield of a chip package.

### BACKGROUND

In order to achieve better performance, maintain a smaller size, and lower power consumption, existing package technology has evolved from the early 2D package toward three-dimensional packages (e.g., 2.5D package).

When 2.5D package is performed, interposer mounted with chip is soldered to the package substrate by a reflow soldering process, such as the initial solder balls on the interposer are soldered to the initial solder paste on the package substrate by a reflow soldering process.

With the large-scale development of chip, the dimensions of chip are also getting greater and greater, warpage deformation of interposer mounted with chip in the reflow soldering process is also getting greater and greater, and too big warpage deformation often leads to soldering problems (e.g., solder bridging, solder joint failure, etc.) or increases the risk of poor soldering.

### SUMMARY

The present disclosure provides a method for improving the reflow soldering yield of a chip package, comprising: at step 1, an initial design structure is provided, the initial design structure comprising a package substrate and an interposer, the package substrate having a plurality of discrete initial solder pastes on an upper surface of the interposer, the interposer having a semiconductor chip mounted to an upper surface of the interposer, and the interposer having a plurality of discrete initial solder balls on a lower surface of the interposer; at step 2, reflow soldering is performed on the initial design structure, initial solder balls on the lower surface of the interposer in the initial design structure is soldered together with corresponding initial solder paste on the upper surface of the package substrate in the initial design structure to form an initial package structure, and the initial solder balls and corresponding the initial solder paste are soldered together to form solder balls of the initial package structure, the initial package structure having a warpage after reflow soldering, and the initial package structure comprising at least one compression area and at least one stretching area, the height of the solder ball in the compression area being smaller than an ideal solder ball height, and the height of the solder ball in the stretching area being greater than an ideal solder ball height, the ideal solder ball height being the ideal height of the solder ball obtained by performing the soldering on the initial design structure without considering the reflow soldering warpage situation; at step 3, the height values of the corresponding solder balls in the compression area and in the stretching area of the initial package structure are obtained by chip warpage simulation or actual measurement, and the diameters of the corresponding solder balls in the compression area and in the stretching area are further obtained based on empirical formula; at step 4, based on the height values and diameters of the corresponding solder balls in the compression area and in the stretching area of the obtained initial package structure, a control rule 1 for the diameters of adjacent solder balls in the compression area and the spacing distance between adjacent solder balls is established and a control rule 2 for the volume of the solder balls in the stretching area and the heights and diameters of the solder balls is established, respectively; at step 5, it is determined whether the solder balls in the compression area of the initial package structure meet control rule 1 and whether the solder balls in the stretching area meet control rule 2, and if no, then step 6 is performed, and if both yes, then step 7 is performed; at step 6, for the compression area which does not meet control rule 1, optimization scheme 1 is used to optimize the parameters of the initial solder paste and/or the initial solder balls in the area corresponding to the compression area in the initial design structure and to make them meet control rule 1; for the stretching area which does not meet control rule 2, optimization scheme 2 is used to optimize the parameters of the initial solder paste and/or the initial solder balls in the area corresponding to the stretching area in the initial design structure and to make them meet control rule 2; wherein the optimization scheme 1 comprises one of or a combination of more of: a way of reducing the volume of the initial solder paste in a corresponding area on the package substrate in the initial design structure, reducing the volume of the initial solder balls in a corresponding area on the interposer in the initial design structure, or a way of increasing the spacing distance between adjacent initial solder balls in a corresponding area on the interposer; and the optimization scheme 2 comprises one of or a combination of more of: a way of increasing the volume of the initial solder paste in a corresponding area on the package substrate in the initial design structure, a way of increasing the volume of the initial solder balls in a corresponding area on the interposer in the initial design structure, or a way of reducing the spacing distance between adjacent initial solder balls in a corresponding area on the interposer; at step 7, an actual production reflow soldering verification is performed on the initial design structure that meet both control rule 1 and control rule 2 as well as the optimized initial design structure, and a soldering quality yields check is performed; at step 8, it is determined whether the solder quality yield meets the design requirements, and if it meets the design requirements, then it ends, and if it does not meet the design requirements, then steps 6-7 are repeated until the design requirements are met.

In some embodiments, the control rule 1 is: ½D_{ci}+½D_{ci+1}≤K₁×L_{i,i+1}, the selection range of K₁ is 50%-80%, and the initial value of K₁ can be taken as 70%, wherein D_{ci} is the diameter Dᵢ of the i-th solder ball in the compression area of the initial package structure or the diameter D_{i′} of the i-th virtual solder ball obtained by the optimized initial design structure, D_{ci+1} is the diameter Dᵢ₊₁ of the (i+1)-th solder ball in the compression area of the initial package structure or the diameter D_{i′+1} of the (i+1)-th virtual solder ball obtained by the optimized initial design structure, L_{i,i+1} is the spacing distance between the i-th initial solder ball in the area corresponding to the compression area in the initial design structure and the adjacent (i+1)-th initial solder ball or is the spacing distance between the i-th initial solder ball in the area corresponding to the compression area in the optimized initial design structure and the adjacent (i+1)-th initial solder ball.

In some embodiments, the diameter Dᵢ of the i-th solder ball in the compression area of the initial package structure and the diameter Dᵢ₊₁ of the (i+1)-th solder ball in the compression area of the initial package structure are obtained by means of the empirical formula 1 and empirical formula 2, respectively, and empirical formula 1 is: Dᵢ=((Vᵢ/πHᵢ+ 1/12K₃Hᵢ²))^{1/2}, and empirical formula 2 is: Dᵢ₊₁=((Vᵢ₊₁/πHᵢ₊₁+ 1/12K₃Hᵢ₊₁²))^{1/2}; wherein K₃ is a compression coefficient of the solder balls, Vᵢ is the volume of the i-th solder ball in the compression area of the initial package structure, and Vᵢ is equal to the sum of the volume Vᵢ₁ of the i-th initial solder paste and the volume Vᵢ₂ of the i-th initial solder ball in the area corresponding to the compression area in the initial design structure, and Hᵢ is the height of the i-th solder ball in the compression area of the initial package structure obtained by the chip warpage simulation or the actual measurement, Vᵢ₊₁ is the volume of the (i+1)-th solder ball in the compression area of the initial package structure, and Vᵢ₊₁ is equal to the sum of the volume V_{i1′} of the (i+1)-th initial solder paste and the volume V_{i2′} of the i-th initial solder ball in the area corresponding to the compression area in the initial design structure, and Hᵢ₊₁ is the height of the (i+1)-th solder ball in the compression area of the initial package structure obtained by the chip warpage simulation or the actual measurement.

In some embodiments, the diameter D_{i′} of the corresponding i-th virtual solder ball in the optimized initial design structure and the diameter D_{i′+1} of the corresponding (i+1)-th virtual solder ball in the optimized initial design structure are obtained by empirical formula 3 and empirical formula 4, respectively, and empirical formula 3 is D_{i′}=((V_{i′}/πHᵢ+ 1/12K₃Hᵢ²))^{1/2} and empirical formula 4 is D_{i′+1}=((V_{i′+1}/πHᵢ₊₁+ 1/12K₃Hᵢ₊₁²))^{1/2}; wherein K3 is a compression coefficient of the solder balls, V_{i′} is the volume of the i-th virtual solder ball accordingly obtained by the optimized initial design structure, and V_{i′} is equal to the sum of the optimized or unoptimized volume of the i-th initial solder paste and the optimized or unoptimized volume of the i-th initial solder ball in the area corresponding to the compression area in the initial design structure, Hᵢ is the height of the i-th solder ball in the compression area of the initial package structure obtained by chip warpage simulation or actual measurement, V_{i′+1} is the volume of the corresponding (i+1)-th virtual solder ball in the optimized initial design structure, and V_{i′+1} is equal to the sum of the optimized or unoptimized volume of the (i+1)-th initial solder paste and the optimized or unoptimized volume of the (i+1)-th initial solder ball volume in the area corresponding to the compression area in the initial design structure, and Hᵢ₊₁ is the height of the (i+1)-th solder ball in the compression area of the initial package structure obtained by chip warpage simulation or actual measurement.

In some embodiments, when repeating steps 6-7, the value of K₁ in the control rule 1 is reduced; reducing the value of K₁ in the control rule 1 comprising: reducing the K₁ from the initial value to a value within a selected range of the K₁.

In an optional embodiment, the control rule 2 is: V_{ci}≥K₂×⅙πD_{ci}²Hᵢ, the selection range of K₂ is 1.1-2, and the initial value of K₂ can be taken as 1.2, wherein V_{ci} is the volume Vᵢ of the i-th solder ball in the stretching area of the initial package structure or the volume V_{i′} of the i-th virtual solder ball accordingly obtained by the optimized initial design structure, D_{ci} is the diameter Dᵢ of the i-th solder ball in the compression area of the initial package structure or the diameter D_{i′} of the i-th virtual solder ball accordingly obtained by the optimized initial design structure, and Hᵢ is the height of the i-th solder ball in the compression area of the initial package structure obtained by the chip warpage simulation or the actual measurement.

In some embodiments, the diameter Dᵢ of the i-th solder ball in the stretching area of the initial package structure and the diameter D_{i′} of the i-th virtual solder ball accordingly obtained from the optimized initial design structure are obtained by means of the empirical formula 5 and the empirical formula 6, respectively, and empirical formula 5 is: Dᵢ=((Vᵢ/πHᵢ− 1/12K₄Hᵢ²))^{1/2}, and empirical formula 6 is: D_{i′}=((V_{i′}/πHᵢ− 1/12K₄Hᵢ²))^{1/2}; wherein K₄ is the stretching coefficient of the solder balls, Vᵢ is the volume of the i-th solder ball in the stretching area of the initial package structure, and Vᵢ is equal to the sum of the volume Vᵢ₁ of the i-th initial solder paste and the volume Vᵢ₂ of the i-th initial solder ball in the area corresponding to the stretching area in the initial design structure, and V_{i′} is the volume of the i-th virtual solder ball accordingly obtained by the optimized initial design structure, and Hᵢ is the height of the i-th solder ball in the stretching area of the initial package structure obtained by chip warpage simulation or actual measurement.

In some embodiments, when repeating steps 6-7, the value of K₂ in the control rule 2 is increased; increasing the value of K₂ in the control rule 2 comprises increasing the K₂ from the initial value to a value within a selected range of the K₂.

In some embodiments, the optimization scheme 1 comprises one of or a combination of two or three of: a way of reducing the volume of the initial solder paste in a corresponding area on the package substrate in the initial design structure, reducing the volume of the initial solder balls in a corresponding area on the interposer in the initial design structure, or a way of increasing the spacing distance between adjacent initial solder balls in a corresponding area on the interposer.

In some embodiments, the optimization scheme 2 comprises one of or a combination of two or three of: a way of increasing the volume of the initial solder paste in a corresponding area on the package substrate in the initial design structure, a way of increasing the volume of the initial solder balls in a corresponding area on the interposer in the initial design structure, or a way of reducing the spacing distance between adjacent initial solder balls in a corresponding area on the interposer.

In some embodiments, in the initial design structure, the volumes of the plurality of discrete initial solder pastes on the upper surface of the package substrate are the same, the volumes of the plurality of discrete initial solder balls on the lower surface of the interposer are the same, and the spacing distances between adjacent initial solder balls are the same.

In some embodiments, the warpage of the initial package structure is in the shape of a “ [symbol] ”, the initial package structure comprises at least a first compression area located in the middle and a first stretching area located at the edge, and the height of the solder ball of the first compression area is smaller than the ideal solder ball height, the height of the solder balls in the first stretching area is greater than the ideal solder ball height; the package substrate and interposer in the initial design structure both have a first area corresponding to the first compression area and a second area corresponding to the first stretching area; the optimization scheme 1 comprises optimizing the initial design structure by using one of or a combination of more of: a way of reducing the volume of the initial solder paste in the first area on the package substrate in the initial design structure, a way of reducing the volume of the initial solder balls in the first area on the interposer in the initial design structure, or a way of increasing the spacing distance between adjacent initial solder balls in the first area on the interposer; the optimization scheme 2 comprises optimizing the initial design structure by using one of or a combination of more of: a way of increasing the volume of the initial solder paste in the second area on the package substrate in the initial design structure, a way of increasing the volume of the initial solder balls in the second area on the interposer in the initial design structure, or a way of reducing the spacing distance between adjacent initial solder balls in the second area on the interposer.

In some embodiments, the warpage of the initial package structure is in the shape of a “ [symbol] ”, the initial package structure comprises at least a first stretching area located in the middle and a first compression area located at the edge, the height of the solder balls in the first stretching area is greater than the ideal solder ball height, the height of the solder balls in the first compression area is smaller than the ideal solder ball height; the package substrate and interposer in the initial design structure both have a first area corresponding to the first compression area and a second area corresponding to the first stretching area; the optimization scheme 1 comprises optimizing the initial design structure by using one of or a combination of more of: a way of reducing the volume of the initial solder paste in the second area on the package substrate in the initial design structure, a way of reducing the volume of the initial solder balls in the second area on the interposer in the initial design structure, or a way of increasing the spacing distance between adjacent initial solder balls in the second area on the interposer; the optimization scheme 2 comprises optimizing the initial design structure by using one of or a combination of more of: a way of increasing the volume of the initial solder paste in the first area on the package substrate in the initial design structure, a way of increasing the volume of the initial solder balls in the first area on the interposer in the initial design structure, or a way of reducing the spacing distance between adjacent initial solder balls in the first area on the interposer.

In some embodiments, the warpage of the initial package structure is in the shape of a “W”, the initial package structure comprises at least a first stretching area located in the middle, a first compression area located on both sides of the first stretching area, and a second stretching area located on the edge, the height of the solder balls in the first stretching area and the second stretching area are greater than the ideal solder ball height; the height of the solder balls in the first compression area is smaller than the ideal solder ball height; the package substrate and interposer in the initial design structure both have a first area corresponding to the first stretching area, a second area corresponding to the first compression area, and a third area corresponding to the second stretching area; the optimization scheme 1 comprises optimizing the initial design structure by using one of or a combination of more of: a way of reducing the volume of the initial solder paste in the second area on the package substrate in the initial design structure, a way of reducing the volume of the initial solder balls in the second area on the interposer in the initial design structure, or a way of increasing the spacing distance between adjacent initial solder balls in the second area on the interposer; the optimization scheme 2 comprises optimizing the initial design structure by using one of or a combination of more of: a way of increasing the volume of the initial solder paste in the first area and the third area on the package substrate in the initial design structure, a way of increasing the volume of the initial solder balls in the first area and the third area on the interposer in the initial design structure, or a way of reducing the spacing distance between adjacent initial solder balls in the first area and the third area on the interposer.

In some embodiments, the warpage of the initial package structure is in the shape of a “M”, the initial package structure comprises at least a first compression area located in the middle, a first stretching area located on both sides of the first compression area, and a second compression area located on the edge, the height of the solder balls in the first stretching area are greater than the ideal solder ball height; the height of the solder balls in the first compression area and the second compression area is smaller than the ideal solder ball height; the package substrate and interposer in the initial design structure both have a first area corresponding to the first compression area, a second area corresponding to the first stretching area, and a second area corresponding to the second compression area; the optimization scheme 1 comprises optimizing the initial design structure by using one of or a combination of more of: a way of reducing the volume of the initial solder paste in the first area and the second area on the package substrate in the initial design structure, a way of reducing the volume of the initial solder balls in the first area and the second area on the interposer in the initial design structure, or a way of increasing the spacing distance between adjacent initial solder balls in the first area and the second area on the interposer; the optimization scheme 2 comprises optimizing the initial design structure by using one of or a combination of more of: a way of increasing the volume of the initial solder paste in the second area on the package substrate in the initial design structure, a way of increasing the volume of the initial solder balls in the second area on the interposer in the initial design structure, or a way of reducing the spacing distance between adjacent initial solder balls in the second area on the interposer.

In some embodiments, the plurality of discrete initial solder pastes on the upper surface of the package substrate are formed by brushing an initial solder paste material into a plurality of discrete mesh apertures of a steel mesh; the way of reducing the volume of the initial solder paste in a corresponding area on the package substrate in the initial design structure is achieved by reducing the diameter and/or the height of the mesh apertures of the steel mesh; the way of increasing the volume of the initial solder paste in a corresponding area on the package substrate in the initial design structure is achieved by increasing the diameter and/or the height of the mesh apertures of the steel mesh.

In some embodiments, the package substrate is a PCB substrate or a resin substrate, and the interposer is a silicon interposer or an RDL interposer.

### BRIEF DESCRIPTION OF THE DRAWINGS

FIG. 1 is a process flow schematic diagram of a method for improving the reflow soldering yield of a chip package in an embodiment of the present disclosure;

FIG. 2 is a structural schematic diagram of the initial design structure in an embodiment of the present disclosure;

FIG. 3 is a structural schematic diagram of the initial package structure obtained without considering the reflow soldering warpage in an embodiment of the present disclosure;

FIGS. 4-5 are structural schematic diagrams of the initial package structure obtained considering the reflow soldering warpage in an embodiment of the present disclosure;

FIG. 6 is a structural schematic diagram of the initial package structure in which the warpage exists and is in the shape of a “ [symbol] ” in an embodiment of the present disclosure;

FIG. 7 is a structural schematic diagram of optimizing the volume of the initial solder paste on the package substrate in the initial design structure in an embodiment of the present disclosure;

FIG. 8 is a structural schematic diagram of optimizing the volume of the initial solder balls on the interposer in the initial design structure in an embodiment of the present disclosure;

FIG. 9 is a structural schematic diagram of optimizing the spacing distance between adjacent initial solder balls on the interposer in the initial design structure in an embodiment of the present disclosure;

FIG. 10 is a structural schematic diagram of the initial package structure in which the warpage exists and is in the shape of a “ [symbol] ” in an embodiment of the present disclosure;

FIG. 11 is a structural schematic diagram of optimizing the volume of the initial solder paste on the package substrate in the initial design structure in an embodiment of the present disclosure;

FIG. 12 is a structural schematic diagram of optimizing the volume of the initial solder balls on the interposer in the initial design structure in an embodiment of the present disclosure;

FIG. 13 is a structural schematic diagram of optimizing the spacing distance between adjacent initial solder balls on the interposer in the initial design structure in an embodiment of the present disclosure;

FIG. 14 is a structural schematic diagram of the initial package structure in which the warpage exists and is in the shape of a “W” in an embodiment of the present disclosure;

FIG. 15 is a structural schematic diagram of optimizing the volume of the initial solder paste on the package substrate in the initial design structure in an embodiment of the present disclosure;

FIG. 16 is a structural schematic diagram of optimizing the volume of the initial solder balls on the interposer in the initial design structure in an embodiment of the present disclosure;

FIG. 17 is a structural schematic diagram of optimizing the spacing distance between adjacent initial solder balls on an interposer in the initial design structure in an embodiment of the present disclosure;

FIG. 18 is a structural schematic diagram of the initial package structure in which the warpage exists and is in the shape of an “M” in an embodiment of the present disclosure;

FIG. 19 is a structural schematic diagram of optimizing the volume of the initial solder paste on the package substrate in the initial design structure in an embodiment of the present disclosure;

FIG. 20 is a structural schematic diagram of optimizing the volume of the initial solder balls on the interposer in the initial design structure in an embodiment of the present disclosure; and

FIG. 21 is a structural schematic diagram of optimizing the spacing distance between adjacent initial solder balls on the interposer in the initial design structure in an embodiment of the present disclosure.

### DETAILED DESCRIPTION

Specific embodiments of the present disclosure are described in detail below in conjunction with the accompanying drawings. When describing the embodiments of the present disclosure in detail, the schematic diagrams will be partially enlarged and not in accordance with the general scale for the convenience of illustration, and the schematic diagrams are only examples, which shall not limit the protection scope of the present disclosure herein. In addition, the three-dimensional spatial dimensions of length, width, and depth should be included in the actual production.

How to improve the problem of poor soldering or reduce the risk of poor soldering during the reflow soldering process of chip package is an urgent issue that demands to be solved in the industry.

In the method for improving the reflow soldering yield of a chip package in the present disclosure, after establishing control rule 1 and control rule 2, at first, step 5 is performed to determine whether the solder balls in the compression area of the initial package structure meet control rule 1, and whether the solder balls in the stretching area meet control rule 2, and if they do not meet, then step 6 is performed, and optimization scheme 1 and optimization scheme 2 are adopted respectively to optimize them to make them meet control rule 1 and control rule 2 under the situations that do not meet control rule 1 and control rule 2, after optimization, step 7 is performed, and actual production reflow soldering verification is performed, and soldering quality yield check is performed, if they are both met, then step 7 is directly performed, after step 7, step 8 is performed to determine whether the soldering quality yield meets the design requirements, if the design requirements are met, then the process ends, and if it does not meet the design requirements, then steps 6-7 are repeated until the design requirements are met, in order to improve the problems of poor soldering (e.g., solder bridging and/or solder joint failure problems) of the chip package reflow soldering under different warpage shapes or to reduce the risk of poor soldering of the chip package reflow soldering.

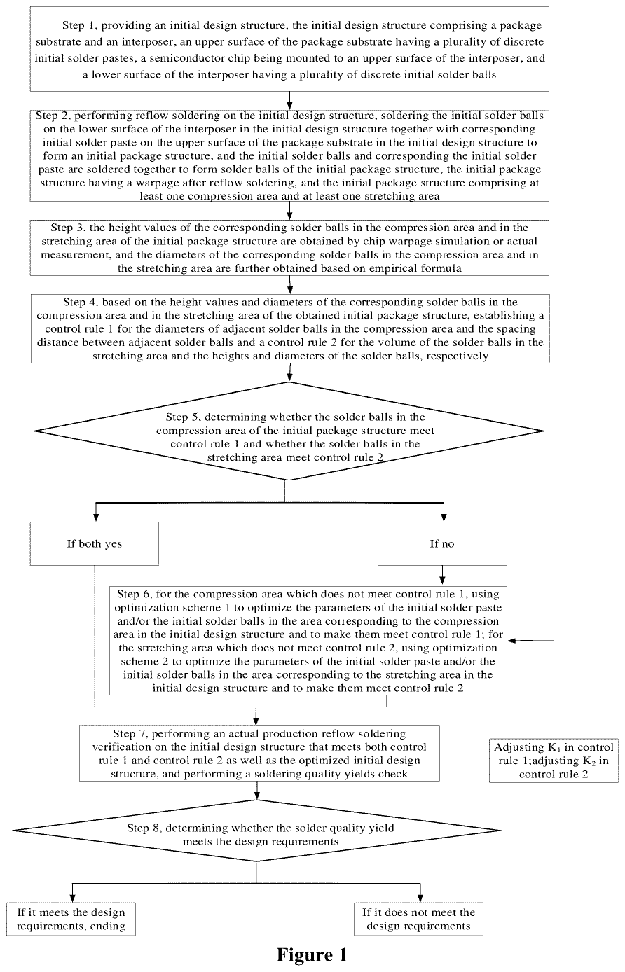

An embodiment of the present disclosure provides a method for improving the reflow soldering yield of a chip package, referring to FIG. 1, the method for improving the reflow soldering yield of a chip package comprises the following.

At step 1, an initial design structure is provided. The initial design structure comprises a package substrate and an interposer, the package substrate having a plurality of discrete initial solder pastes on an upper surface of the package substrate, the interposer having a semiconductor chip mounted to an upper surface of the interposer, and the interposer having a plurality of discrete initial solder balls on a lower surface of the interposer.

At step 2, reflow soldering is performed on the initial design structure. Initial solder balls on the lower surface of the interposer in the initial design structure are soldered together with a corresponding initial solder paste on the upper surface of the package substrate in the initial design structure to form an initial package structure, and the initial solder balls and corresponding the initial solder paste are soldered together to form solder balls of the initial package structure, the initial package structure has warpage after reflow soldering, and the initial package structure comprises at least one compression area and at least one stretching area.

At step 3, the height values of the corresponding solder balls in the compression area and in the stretching area of the initial package structure are obtained by chip warpage simulation or actual measurement, and the diameters of the corresponding solder balls in the compression area and the stretching area are further obtained based on empirical formulas.

At step 4, based on the obtained height values and diameters of the solder balls at different positions of the initial package structure, a control rule 1 for the diameter of adjacent solder balls in the compression area and the spacing distance between adjacent solder balls and a control rule 2 for the volume of the solder balls in the stretching area and the height and diameter of the solder balls are established, respectively.

At step 5, it is determined whether the solder balls in the compression area of the initial package structure meet control rule 1 and whether the solder balls in the stretching area meet control rule 2; if not, then step 6 is performed, and if both yes, then step 7 is performed.

At step 6, for the compression area that does not meet control rule 1, optimization scheme 1 is used to optimize the parameters of the initial solder paste and/or the initial solder balls in the area corresponding to the compression area in the initial design structure and to make them meet control rule 1; for the stretching area which does not meet control rule 2, optimization scheme 2 is used to optimize the parameters of the initial solder paste and/or the initial solder balls in the area corresponding to the stretching area in the initial design structure and to make them meet control rule 2.

At step 7, an actual production reflow soldering verification is performed on the initial design structure that meets both control rule 1 and control rule 2 as well as the optimized initial design structure, and a soldering quality yield check is performed.

At step 8, it is determined whether the solder quality yield meets the design requirements, and if it meets the design requirements, then it ends; if it does not meet the design requirements, then steps 6-7 are repeated until the design requirements are met.

The aforementioned method for improving the reflow soldering yield of a chip package will be described in detail below in conjunction with the accompanying drawings.

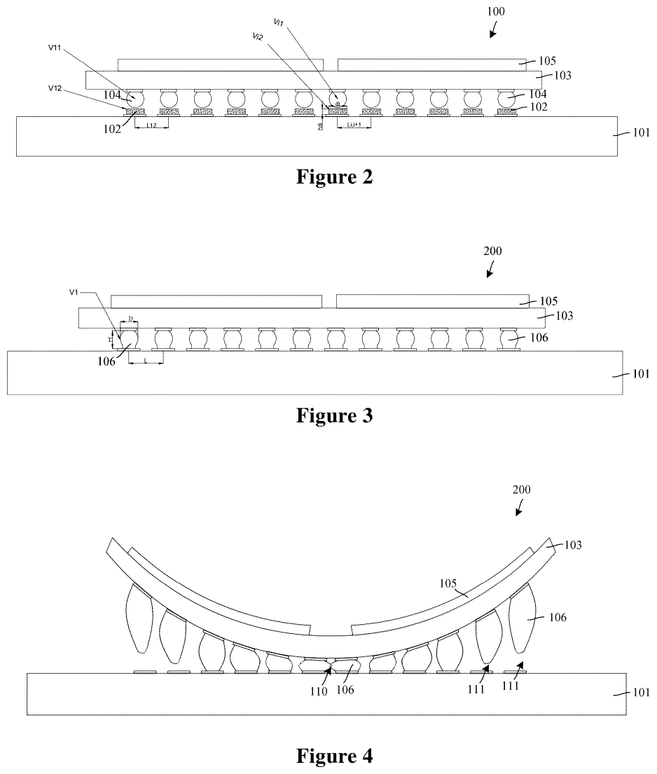

First, referring to FIG. 1 and in conjunction with reference to FIG. 2, step 1 is performed to provide an initial design structure 100, the initial design structure 100 comprising a package substrate 101 and an interposer 103, the package substrate 101 having on its upper surface a plurality of discrete initial solder pastes 102, the interposer 103 having a semiconductor chip 105 mounted to its upper surface, and the interposer 103 having on its lower surface a plurality of discrete initial solder balls 104.

The package substrate 101 serves the functions of electrical connection, protection, support, heat dissipation, and assembly during the packaging process of the chip. In an embodiment, the package substrate 101 comprises opposing upper and lower surfaces, the upper surface of the package substrate 101 having a plurality of discrete first pads (not shown in the figures), the lower surface of the package substrate 101 having a plurality of discrete second pads (not shown in the figures), the package substrate 101 having a first connection line (not shown in the figures), and part of the first connection line can be used for electrical connection between the first pads on the upper surface of the package substrate 101 and corresponding second pads on the lower surface of the package substrate 101, part of the first connection line can also be used for electrical connection between some of the first pads on the upper surface of the package substrate 101, and part of the first connection line can also be used for electrical connection between some of the second pads on the lower surface of the package substrate 101. In a specific embodiment, the package substrate 101 may be a PCB substrate, a resin substrate, or a glass substrate.

The upper surface of the package substrate 101 has a plurality of discrete initial solder pastes 102. The initial solder pastes 102 are subsequently used to be soldered together with corresponding initial solder balls 104 on the lower surface of the interposer 103 by a reflow soldering process to form solder balls. In a specific embodiment, the initial solder paste 102 is formed on the surface of a first pad on the upper surface of the package substrate 101.

In an embodiment, in the initial design structure 100, a plurality of discrete initial solder pastes 102 formed on the upper surface of the package substrate 101 has equal volume. Specifically, the initial solder paste 102 is cylindrical in shape, a plurality of the initial solder pastes 102 have the same diameter and height, and the volume calculation formula of the initial solder paste 102 is Vᵢ₁=¼πdᵢ²h_{di}.

Vᵢ₁ represents the volume of the i-th initial solder paste 102 on the upper surface of the package substrate 101, dᵢ represents the diameter of the i-th initial solder paste 102 on the upper surface of the package substrate 101, and h_{di} represents the height of the i-th initial solder paste 102 on the upper surface of the package substrate 101, i≥1, and as shown in FIG. 2, the left-most one of the initial solder pastes 102 in FIG. 2 is taken as a first initial solder paste, and the volume calculation formula for the first initial solder paste is V₁₁=¼πd₁²h_{d1}.

In an embodiment, the initial solder paste 102 is formed by a steel mesh printing process, and the specific process of forming the initial solder paste 102 is as follows: a steel mesh having a plurality of discrete mesh apertures is provided; the steel mesh is mounted on the upper surface of the package substrate 101; an initial solder paste material is brushed into the mesh apertures; excess initial solder paste material on the surface of the steel mesh is scraped off by means of a squeegee, the initial solder paste material in the mesh apertures remains as initial solder paste 102; the steel mesh is removed. Thus, in an embodiment, the volume of the initial solder paste 102 can also be controlled by the volume of the mesh apertures in the steel mesh, specifically controlled by the diameter and/or height of the mesh apertures.

In an embodiment, the material of the initial solder paste 102 is tin or a tin alloy. The tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

The interposer 103 is used in the packaging process of the chip for electrical connection between the chip and the chip as well as between the chip and the package substrate in order to improve the efficiency and reliability of the signal transmission, to reduce the transmission delay and power consumption, and also to improve the performance and bandwidth of the package structure.

In an embodiment, the interposer 103 comprises opposing upper surface and lower surface, the upper surface of the interposer 103 having a plurality of discrete third pads (not shown in the figures), the lower surface of the interposer 103 has a plurality of discrete fourth pads (not shown in the figures), the interposer 103 has a second connection line (not shown in the figures), the second connection line has a high wiring density, part of the second connection line can be used for electrical connection between the third pads on the upper surface of the interposer 103 and the corresponding fourth pads on the lower surface of the interposer 103, part of the second connection line can also be used for electrical connection between part of the third pads on the upper surface of the interposer 103, and part of the second connection line can also be used for electrical connection between part of the fourth pads on the lower surface of the interposer 103. In a specific embodiment, the interposer 103 may be a silicon interposer or an RDL (Re-distribution Layer) interposer.

The upper surface of the interposer 103 is mounted with a semiconductor chip 105, and the lower surface of the interposer 103 also has a plurality of discrete initial solder balls 104. In a specific embodiment, the semiconductor chip 105 may be electrically connected to the third pads on the upper surface of the interposer 103, and the initial solder balls 104 may be electrically connected to the fourth pads on the lower surface of the interposer 103.

In an embodiment, the semiconductor chips 105 may be mounted to the upper surface of the interposer 103 by a flip-fit process or a front-fit process. The number of the semiconductor chips 105 may be one or more (greater than or equal to 2). In an embodiment, when the semiconductor chips 105 are a plurality, the functions of the plurality of the semiconductor chips 105 may be the same or different. The shape and volume of the plurality of the semiconductor chips 105 may also be the same or different. The semiconductor chips 105 may be logic chips or memory chips.

In an embodiment, in the initial design structure 100, a plurality of discrete initial solder balls 104 formed on the lower surface of the package substrate 101 has an equal volume. The volume calculation formula of the initial solder balls 104 is Vᵢ₂=⅙πdᵢ₂³.

Vᵢ₁ represents the volume of the i-th initial solder balls 104 on the lower surface of the interposer 103, and dᵢ₂ represents the diameter of the i-th initial solder balls 104 on the lower surface of the interposer 103, as shown in FIG. 2, the left-most initial solder balls 104 in FIG. 2 is taken as first initial solder balls, and the volume calculation formula of the first initial solder balls is V₁₂=⅙πd₁₂³.

In an embodiment, the material of the initial solder ball 104 is tin or a tin alloy. The tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

Next, referring to FIG. 1 and in conjunction with reference to FIG. 2 and FIG. 4, step 2 is performed to perform reflow soldering on the initial design structure 100, the initial solder balls 104 (referring to FIG. 2) on the lower surface of the interposer 103 in the initial design structure 100 are soldered together with the corresponding initial solder paste 102 (referring to FIG. 2) on the upper surface of the package substrate 101 in the initial design structure 100 to form an initial package structure 200 (referring to FIG. 4), and the initial solder balls 104 and corresponding the initial solder paste 102 are soldered together to form a solder ball 106 of the initial package structure (referring to FIG. 4), there is warpage in the initial package structure 200, there is warpage in the initial package structure after reflow soldering and the initial package structure 200 comprises at least one compression area and at least one stretching area, the height Hi of the solder ball 106 in the compression area is smaller than the ideal solder ball height H, the height Hi of the solder ball 106 in the stretching area is smaller than the ideal solder ball height H, and the ideal solder ball height H is the ideal height of the solder ball obtained without considering the reflow soldering warpage for the initial design structure 100.

The reflow soldering comprises at least a heating process and a cooling process.

Without considering the reflow soldering warpage situation (in the ideal reflow soldering process), referring to FIG. 3, since the mismatch between the coefficient of thermal expansion (CTE) of the interposer 103 mounted with the semiconductor chip 105 and the coefficient of thermal expansion (CTE) of the package substrate 101 will not be taken into account, i.e., the interposer 103 mounted with the semiconductor chip 105 and the package substrate 101 will not be warped or deformed in the reflow soldering process, the initial package structure 200 formed is also in a ideal state, and there is no warpage or deformation, a plurality of solder balls 106 in the initial package structure 200 are also in an ideal state, there is no problem of poor soldering, the height H of a plurality of solder balls 106 can be kept the same, the diameter D can be kept the same, the pitch L can be kept the same, and the volume V1 can be kept the same, and in this case, the height H of the solder balls 106 in the structure 200 obtained is the ideal solder ball height H described previously.

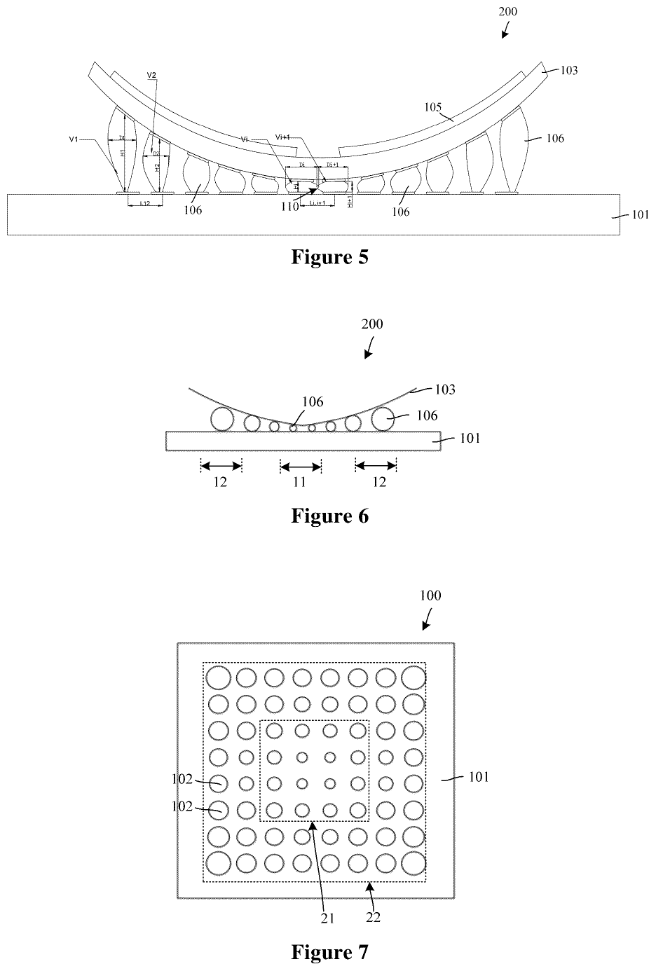

In actual reflow soldering, continue to referring to FIG. 4, due to the mismatch or incompatibility between the coefficient of thermal expansion (CTE) of the interposer 103 mounted with the semiconductor chip 105 and the coefficient of thermal expansion (CTE) of the package substrate 101, the interposer 103 and the package substrate 101 will generate warpage or deformation in the actual reflow soldering process or after reflow soldering, the warpage or deformation of the interposer 103 and package substrate 101 may cause the solder balls 106 in the initial package structure 200 to have poor soldering problems (e.g., problems such as the presence of solder bridging between the solder balls 106, the presence of solder joint failure between solder balls 106 and package substrate 101, etc.) or increase the risk of poor soldering of the solder balls 106 (e.g., the risk of solder bridging between the solder balls 106, the risk of solder joint failure between the solder balls 106 and the package substrate 101). Specifically, when the warpage value of the interposer 103 and the package substrate 101 is large, during the actual reflow soldering process or after reflow soldering, solder bridging 110 (in a position of reduced gap between the interposer 103 and the package substrate 101, where the solder balls 106 are squeezed to cause solder bridging 110 between adjacent solder balls 106) and/or solder joint failure 111 (in a position of increased gap between the interposer 103 and the package substrate 101, where the solder balls 106 initial solder balls are pulled to cause solder joint failure between the solder balls 106 and the package substrate 101). It is to be noted that in some embodiments, for the sake of convenient illustration, only the occurrence of the warpage of the interposer 103 is shown in FIG. 4 and FIG. 5 and in other subsequent accompanying drawings. In other embodiments, the interposer 103 and package substrate 101 will warp simultaneously.

Formation of the initial package structure 200 may be obtained by actual production or may be obtained by chip warpage simulation software simulation, and when performing the simulation, reflow soldering warpage needs to be taken into account.

The presence of warpage of the interposer 103 and package substrate 101 in the initial package structure 200 may result in the presence of poor soldering problems of solder bridging and solder joint failure simultaneously in the solder balls 106 in the initial package structure 200 (e.g., both solder bridging 110 and solder joint failure 111 are present in FIG. 4), or there may be only one of the poor soldering problems of solder bridging and solder joint failure (e.g., only solder bridging 110 is present in FIG. 5), or there may be not presence of actual solder bridging and solder joint failure problems but may be presence of problems that increase the risk of poor soldering of solder bridging and solder joint failure (e.g., a greater risk of solder joint failure between the two leftmost and rightmost solder balls 106 and the package substrate 101 is present in FIG. 5), and the subsequent methods of the present disclosure are aimed to solve the aforementioned problems.

When there is a warpage of the interposer 103 and package substrate 101 in the initial package structure 200, the initial package structure 200 will comprise at least one compression area and at least one stretching area, wherein the heights of the solder balls 106 at different positions will be different, the compression area is the area where the solder balls 106 are squeezed, and the height Hi of the solder balls 106 in the compression area will be smaller than the ideal solder ball height H, and the stretching area is the area where the solder balls 106 are stretched, and the height Hi of the solder balls 106 in the stretching area will be greater than the ideal solder ball height H. The ideal solder ball height is the ideal height of the solder ball obtained by performing the soldering on the initial design structure without considering the reflow soldering warpage situation (as shown in FIG. 3), and the specific value of the ideal solder ball height H can be obtained by simulation or calculated by empirical formula.

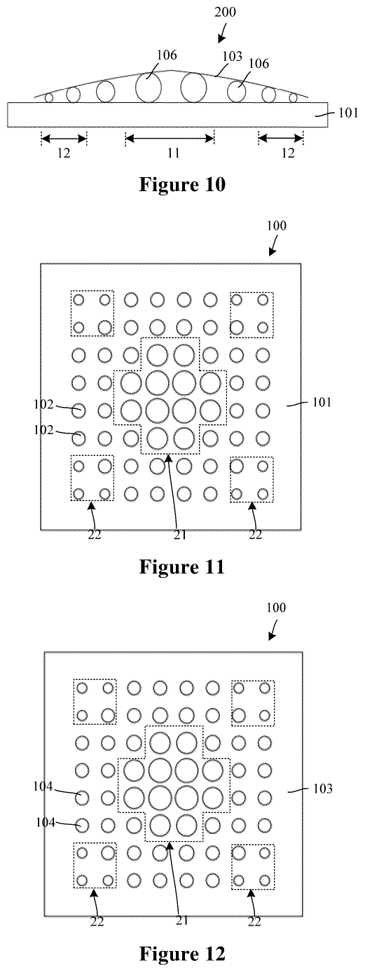

The initial package structure 200 can have different shapes when warped. In an embodiment, the initial package structure 200 is warped in the shape of “ [symbol] ” (referring to FIG. 6). In another embodiment, the initial package structure 200 is warped in the shape of “ [symbol] ” (referring to FIG. 10). In another embodiment, the initial package structure 200 is warped in the shape of “W” (referring to FIG. 14). In another embodiment, the initial package structure 200 is warped in the shape of “M” (referring to FIG. 18). Therefore, the subsequent methods of the present disclosure can improve the problem of poor soldering of the chip package reflow soldering or reduce the risk of poor soldering of the chip package reflow soldering for different warpage shapes of the initial package structure 200.

Next, referring to FIG. 1 and in conjunction with reference to FIG. 5, step 3 is performed to obtain the height values Hi of the corresponding solder balls 106 in the compression area and the stretching area of the initial package structure 200 by chip warpage simulation or by actual measurement, and to further obtain the diameters Di of the corresponding solder balls in the compression area and in the stretching area according to empirical formulas.

In an embodiment, when the height Hi of the solder ball 106 is obtained by actual measurement, the initial package structure 200 shown in FIG. 5 is obtained by actual production, and then an actual measurement of the height of the solder ball 106 in the initial package structure 200 is performed. The actual measurement is a destructive measurement, the solder ball 106 to be measured needs to be dissected before the measurement is performed, and after the dissecting, the measurement of the height Hi of the solder ball 106 is performed.

In another embodiment, when the height Hi of the solder ball 106 is obtained by warpage simulation, the warpage simulation process may be performed using professional warpage simulation software.

The diameter Di of the solder balls 106 is obtained by means of an empirical formula. The empirical formula used for the diameter Di of the solder balls 106 in the compression area of the initial package structure 200 is different from the empirical formula used for the diameter Di of the solder balls 106 in the stretching area.

In an embodiment, the diameter Dᵢ of the i-th solder ball 106 in the compression area of the initial package structure 200 and the diameter Dᵢ₊₁ of the (i+1)-th solder ball 106 in the compression area of the initial package structure 200 are obtained by means of empirical formula 1 and empirical formula 2, respectively.

The empirical formula 1 is: Dᵢ=((Vᵢ/πHᵢ+ 1/12K₃Hᵢ²))^{1/2}, and the empirical formula 2 is: Dᵢ₊₁=((Vᵢ₊₁/πHᵢ₊₁+ 1/12K₃Hᵢ₊₁²))^{1/2}, where K₃ is a compression coefficient of the solder balls, obtained experimentally or empirically, Vᵢ is the volume of the i-th solder ball 106 in the compression area of the initial package structure 200, and Vᵢ is equal to the sum of the volume of the i-th initial solder paste Vᵢ₁ and the volume of the i-th initial solder ball Vᵢ₂ in the area corresponding to the compression area in the initial design structure 100, i.e., Vᵢ=Vᵢ₁+Vᵢ₂, for the formulas for calculating Vᵢ₁ and Vᵢ₂, refer to the corresponding parts of the aforementioned, Vᵢ₁ and Vᵢ₂ are known, and thus Vᵢ is known, and Hᵢ is the height of the i-th solder ball 106 in the compression area of the initial package structure obtained by chip warpage simulation or actual measurement, and is also known, and thus diameter Dᵢ of the i-th solder ball 106 in the compression area of the initial package structure 200 can be obtained by the empirical formula 1; Vᵢ₊₁ is the volume of the (i+1)-th solder ball 106 in the compression area of the initial package structure 200, and Vᵢ₊₁ is equal to the sum of the volume of the (i+1)-th initial solder paste Vᵢ₁ and the volume of the (i+1)-th initial solder ball Vᵢ₂ in the area corresponding to the compression area in the initial design structure 100, i.e., Vᵢ₊₁ is similar to Vᵢ as to the calculation process, and is also known, and Hᵢ₊₁ is the height of the (i+1)-th solder ball in the compression area of the initial package structure obtained by chip warpage simulation or actual measurement, and is also known, and thus diameter Dᵢ₊₁ of the (i+1)-th solder ball 106 in the compression area of the initial package structure 200 can be obtained by the empirical formula 2. It is to be noted that in this embodiment, it is only exemplary that the diameter Dᵢ of the i-th solder ball 106 in the compression area of the initial package structure 200 and the diameter Dᵢ₊₁ of the (i+1)-th solder ball 106 in the compression area of the initial package structure 200 are obtained by means of the empirical formula 1 and the empirical formula 2 described in the aforementioned, respectively, and in other embodiments, the diameter Dᵢ of the i-th solder ball 106 in the compression area of the initial package structure 200 and the diameter Dᵢ₊₁ of the (i+1)-th solder ball 106 in the compression area of the initial package structure 200 can be obtained by other existing empirical formulas, respectively.

In an embodiment, the diameter Di of the i-th solder ball 106 in the stretching area of the initial package structure 200 is obtained by means of empirical formula 5. The empirical formula 5 is: Dᵢ=((Vᵢ/πHᵢ− 1/12K₄Hᵢ²))^{1/2}, where K₄ is a stretching coefficient of the solder balls, obtained experimentally or empirically, Vᵢ is the volume of the i-th solder ball in the stretching area of the initial package structure, and Vᵢ is equal to the sum of the volume Vᵢ₁ of the i-th initial solder paste and the volume Vᵢ₂ of the i-th initial solder ball in the area corresponding to the stretching area of the initially designed structure, Vᵢ=Vᵢ₁+Vᵢ₂, for the formulas for calculating Vᵢ₁ and Vᵢ₂, refer to the corresponding parts of the aforementioned, Vᵢ₁ and Vᵢ₂ are known, and thus Vᵢ is known, and Hᵢ is the height of the i-th solder ball in the stretching area of the initial package structure obtained by chip warpage simulation or actual measurement, and is also known, and thus the diameter Dᵢ of the i-th solder ball 106 in the stretching area of the initial package structure 200 can be obtained by empirical formula 5. It is to be noted that in this embodiment, it is only exemplary that the diameter Di of the i-th solder ball 106 in the stretching area of the initial package structure 200 is obtained by means of the empirical formula 5 as described in the aforementioned, and in other embodiments, the diameter Dᵢ of the i-th solder ball 106 in the stretching area of the initial package structure 200 may be obtained by means of other existing empirical formulas.

Next, continue to refer to FIG. 1 and FIG. 5, step 4 is performed to establish a control rule 1 for the diameter of adjacent solder balls and the spacing distance between adjacent solder balls in the compression area and a control rule 2 for the volume of solder balls and the height and diameter of the solder balls in the stretching area, based on the obtained height value Hi and the diameter Di of the corresponding solder balls 106 in the compression area and in the stretching area of the initial package structure 200 as described above, respectively.

In an embodiment, the control rule 1 is: ½D_{ci}+½D_{ci+1}≤K₁×L_{i,i+1}, where K1 is selected in the range of 50%-80%, specifically, it can be 50%, 60%, 70%, 80%, and the initial value of K1 may be taken as 70% when the method of the present disclosure is performed, wherein D_{ci} is the diameter Dᵢ of the i-th solder ball 106 in the compression area of the initial package structure 200 (the calculation process is described previously) or is the diameter D_{i′} of the i-th virtual solder ball obtained by the corresponding initial design structure optimized subsequently (the calculation process is described subsequently), D_{ci+1} is the diameter Dᵢ₊₁ of the (i+1)-th solder ball in the compression area of the initial package structure 200 or is the diameter D_{i′+1} of the (i+1)-th virtual solder ball obtained by the initial design structure optimized subsequently, L_{i,i+1} is the spacing distance between the i-th initial solder ball 104 in the area corresponding to the compression area in the initial design structure 100 (referring to FIG. 2) and the adjacent (i+1)-th initial solder ball 104 (L_{i,i+1} is a known parameter in the initial design structure 100) or is the spacing distance between the i-th initial solder ball and the adjacent (i+1)-th initial solder ball in the area corresponding to the compression area in the optimized initial design structure 100 (L_{i,i+1} is also known after optimization). It should be noted that when optimization is performed subsequently, if the spacing distance between adjacent initial solder balls 104 corresponding to the object being optimized (e.g., the solder paste 102 or the initial solder balls 104) remains unchanged, L_{i,i+1} in the control rule 1 is the spacing distance between the i-th initial solder ball and the adjacent (i+1)-th initial solder ball in the initial design structure 100 when the judgment as to whether the object being optimized meets the control rule 1 is performed; and when optimization is performed subsequently, if the object to be optimized is the spacing distance between the i-th initial soldering ball and the (i+1)-th adjacent initial soldering ball in the initial design structure 100, L_{i,i+1} in the control rule 1 is the spacing distance between the i-th initial soldering ball and the adjacent (i+1)-th initial soldering ball in the optimized initial design structure 100 when the judgment as to whether the object being optimized meets the control rule 1 is performed. It is to be noted that when there is a plurality of compression areas in the initial package structure 200, the taken value of the K₁ may be different for different compression areas. For example, in areas that are more severely compressed, the taken value of the K₁ may be smaller, but it still needs to be within the selection range. Moreover, in the method of the present disclosure, when step 6 and step 7 are repeated subsequently, the taken value of K₁ can change based on the initial value, such as reducing from the initial value, but it still needs to be within the selection range.

In an embodiment, the control rule 2 is: V_{ci}≥K₂×⅙πD_{ci}²Hᵢ, where K₂ is selected in the range of 1.1-2, specifically, it can be 1.1, 1.2, 1.3, 1.4, 1.5, 1.6, 1.7, 1.8, 1.9, 2, and the initial value of K₂ may be taken as 1.2 when the method of the present disclosure is performed, wherein V_{ci} is the volume Vᵢ of the i-th solder balls in the stretching area of the initial package structure 200 (it is known, and the calculation process is described in the preceding description) or is the volume V_{i′} of the i-th virtual solder ball subsequently obtained from the optimized initial design structure (the calculation process is described subsequently), D_{ci} is the diameter D of the i-th solder ball in the stretching area of the initial package structure (the calculation process is described in the preceding description) or the diameter D_{i′} of the i-th virtual solder ball subsequently obtained from the optimized initial design structure (the calculation process is described subsequently), and Hᵢ is the height of the i-th solder ball in the compression area of the initial package structure obtained by chip warpage simulation or actual measurement (the calculation process is described in the preceding description). It is to be noted that when there is a plurality of stretching areas in the initial package structure 200, the taken value of the K₂ may be different for different stretching areas. For example, the taken value of the K₂ may be greater in areas that are more severely compressed, but it still needs to be the selection range. Moreover, in the method of the present disclosure, when step 6 and step 7 are repeated subsequently, the taken value of K₂ can change based on the initial value, such as an increase from the initial value, but it still needs to be within the selection range.

Next, continue to refer to FIG. 1 and FIG. 5, step 5 is performed to determine whether the solder balls 106 in the compression area of the initial package structure 200 satisfy control rule 1 and whether the solder balls 106 in the stretching area satisfy control rule 2, and if they do not, then step 6 is performed, and if they both do, then step 7 is performed.

The non-satisfaction comprises one or two of: solder balls 106 in the compression area of the initial package structure 200 do not meet control rule 1, solder balls 106 in the stretching area of the initial package structure 200 do not meet control rule 2.

The simultaneous satisfaction comprises solder balls 106 in the compression area of the initial package structure 200 meet control rule 1, and solder balls 106 in the stretching area of the initial package structure 200 meet control rule 2.

When determining whether the solder balls 106 in the compression area of the initial package structure 200 meet control rule 1, the diameter Dᵢ of the i-th solder ball 106 in the compression area of the initial package structure 200 obtained in step 3, and the diameter Dᵢ₊₁ of the (i+1)-th solder ball 106 in the compression area of the initial package structure 200 are substituted into the aforementioned control rule 1, and it is determined whether ½Dᵢ+½Dᵢ₊₁ is ≤K₁×L_{i,i+1}, and if the sum of ½Dᵢ+½Dᵢ₊₁ is smaller than or equal to K₁×L_{i,i+1}, then the i-th solder ball 106 and the (i+1)-th solder ball 106 in the compression area meet control rule 1, and if the sum of ½Dᵢ+½Dᵢ₊₁ is not smaller than or equal to K₁×L_{i,i+1}, then the i-th solder ball 106 and the i+1 solder ball 106 in the compression area do not meet control rule 1, and optimization is performed subsequently.

When determining whether the solder balls 106 in the stretching area of the initial package structure 200 meet the control rule 2, the volume Vᵢ of the i-th solder ball in the stretching area of the initial package structure 200 (which is known, and the calculation process is described in the preceding description), the diameter Dᵢ of the i-th solder ball in the stretching area of the initial package structure obtained in step 3 (the calculation process is described in the preceding description), the height Hᵢ of the i-th solder ball in the compression area of the initial package structure obtained in step 3 after chip warpage simulation or actual measurement are substituted into aforementioned the control rule 2, and it is determined whether Vᵢ is ≥K₂×⅙πDᵢ²Hᵢ, and if Vᵢ is greater than or equal to K₂×⅙πDᵢ²Hᵢ, then the i-th solder ball 106 in the stretching area meets the control rule 2, if Vᵢ is not greater than or equal to K₂×⅙πDᵢ²Hᵢ, then the i-th solder ball 106 in the stretching area is optimized subsequently.

Next, referring to FIG. 1 and in conjunction with reference to FIGS. 6-9, step 6 is performed, for the compression area (e.g., the first compression area 11 in FIG. 6) that does not meet control rule 1, optimization scheme 1 is used to optimize the parameters of the initial solder paste 102 and/or the initial solder balls 104 in the area corresponding to the compression area (e.g., the first area 21 corresponding to the first compression area 11 in FIGS. 7-9) in the initial design structure 100 and to made them meet control rule 1; for the stretching area (e.g., the first stretching area 12 in FIG. 6) that does not meet control rule 2, optimization scheme 2 is used to optimize the parameters of the initial solder paste 102 and/or the initial solder balls 104 in the area corresponding to the stretching area (e.g., the second area 22 corresponding to the first stretching area 12 in FIGS. 7-9) in the initial design structure 100 and to make them meet control rule 2.

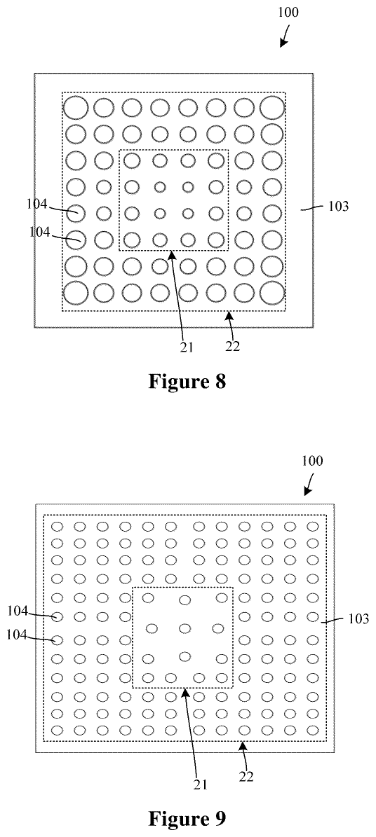

The optimization scheme 1 comprises one of or a combination of more of: a way of reducing the volume of the initial solder paste 102 in a corresponding area on the package substrate 101 (e.g., the first area 21 in FIG. 7) in the initial design structure 200, reducing the volume of the initial solder balls 104 in a corresponding area on the interposer 103 (e.g., the first area 21 in FIG. 8) in the initial design structure 100, or a way of increasing the spacing distance between adjacent initial solder balls 104 in corresponding areas on the interposer 103 (e.g., the first area 21 in FIG. 9).

The optimization scheme 2 comprises one of or a combination of more of: a way of increasing the volume of the initial solder paste 102 in a corresponding area on the package substrate 101 (e.g., the second area 22 in FIG. 7) in the initial design structure 100, a way of increasing the volume of the initial solder balls 104 in a corresponding area on the interposer 103 (e.g., the second area 22 in FIG. 8) in the initial design structure 100 or a way of reducing the spacing distance between adjacent initial solder balls 104 in corresponding areas on the interposer 103 (e.g., the second area 22 in FIG. 9).

In an embodiment, when optimization scheme 1 is used to optimize the parameters of the initial solder paste and/or the initial solder balls in the area corresponding to the compression area in the initial design structure 100, the optimization scheme 1 comprises one of or a combination of two or three of: a way of reducing the volume of the initial solder paste 102 in a corresponding area on the package substrate 101 in the initial design structure 100, a way of reducing the volume of the initial solder ball 104 in a corresponding area on the interposer 103 in the initial design structure 100, or a way of increasing the spacing distance between adjacent initial solder balls 104 in a corresponding area on the interposer 103.

In an embodiment, when optimization scheme 2 is used to optimize the parameters of the initial solder paste and/or the initial solder ball in the area corresponding to the stretching area in the initial design structure 100, the optimization scheme 2 comprising one of or a combination of two or three of: a way of increasing the volume of the initial solder paste 102 in a corresponding area on the package substrate 101 in the initial design structure 100, a way of increasing the volume of the initial solder ball 104 in a corresponding area on the interposer 103 in the initial design structure 100, or a way of reducing the spacing distance between adjacent initial solder balls 104 in a corresponding area on the interposer 103.

When optimization is performed using optimization scheme 1 on the compression area that does not meet control rule 1, it is also necessary to make the optimized scheme meet control rule 1; if control rule 1 is not met, it is necessary to further reduce the volume of the initial solder paste 102 in optimization scheme 1 that is being optimized, or to further reduce the volume of the solder balls 104, or to further increase the distance between adjacent solder balls 104 until the control rule 1 is met. In a specific embodiment, for example, when the optimization scheme 1 that has been performed takes the form of: reducing the volume of the i-th initial solder paste 102 and the volume of the (i+1)-th initial solder paste 102 in a corresponding area on the package substrate 101 in the initial design structure 200 (e.g., the first area 21 in FIG. 7), and when no optimization is performed on the volume of the solder balls 104 and spacing distance between adjacent solder balls 104 in corresponding areas (e.g., the first area 21 in FIG. 8 and FIG. 9) on the package substrate 101 in the initial design structure 200, after reduction (after optimization) of the volume of the i-th initial solder paste 102 and the (i+1)-th initial solder paste 102 in corresponding areas (e.g., the first area 21 in FIG. 7) on the package substrate 101 in the initial design structure 200, it is necessary to obtain the diameter D_{i′} of the i-th virtual solder ball and the diameter D_{i′+1} of the i+1 virtual solder ball accordingly obtained by the optimized initial design structure, and substitute D_{i′} and D_{i′+}1 into the aforementioned control rule 1 to determine or verify whether the sum of ½D_{i′}+½D_{i′+1} is smaller than or equal to K₁×L_{i,i+1}, and if the sum of ½D_{i′}+½D_{i′+1} is smaller than or equal to K₁×L_{i,i+1}, then the performed optimization scheme 1 meets the control rule 1, and otherwise, the performed optimization scheme 1 does not meet the control rule 1, and further adjustments need to be made to the performed optimization scheme 1, for example, to make the parameters that have been adjusted further reduced or increased, or to increase the combinations of the optimizations (e.g., the use of one of the optimization schemes 1 described in the aforementioned turns into the use of a combination of two or three). The specific calculation process of D_{i′} and D_{i′+1} are described below.

In an embodiment, the diameter D_{i′} of the corresponding i-th virtual soldering ball in the optimized initial design structure and the diameter D_{i′+1} of the corresponding i+1 virtual soldering ball in the optimized initial design structure are obtained by means of the empirical formula 3 and the empirical formula 4, respectively.

Empirical formula 3 is: D_{i′}=((V_{i′}/πHᵢ+ 1/12K₃Hᵢ²))^{1/2}, and empirical formula 4 is: D_{i′+1}=((V_{i′+1}/πHᵢ₊₁+ 1/12K₃Hᵢ₊₁²))^{1/2}, where K₃ is the compression coefficient of the solder balls, V_{i′} is the volume of the i-th virtual solder ball accordingly obtained by the optimized initial design structure, and V_{i′} is equal to the sum of the optimized or unoptimized volume of the i-th initial solder paste and the optimized or unoptimized volume of the i-th initial solder ball in the area corresponding to the compression area in the initial design structure, specifically, when the i-th initial solder paste is optimized and the corresponding i-th initial solder ball is unoptimized, the volume V_{i′} of the i-th virtual solder ball is equal to the sum of the optimized volume V_{i1′} of the i-th initial solder paste in the area corresponding to the compression area in the initial design structure and the corresponding unoptimized volume Vᵢ₂ of the i-th initial solder ball in the initial design structure, i.e., V_{i′}=V_{i1′}+Vᵢ₂, V_{i′} and Vᵢ₂ are obtained by the aforementioned volume calculation formula of solder paste and volume calculation formula of solder balls, respectively, V_{i′} and Vᵢ₂ are known, i.e., V_{i′} is known, Hᵢ is the height of the i-th solder ball in the compression area of the initial package structure obtained by chip warpage simulation or actual measurement, and Hᵢ is known, and thus, D_{i′} can be obtained through the empirical formula 3, V_{i′+1} is the volume of the corresponding (i+1)-th virtual solder ball in the optimized initial design structure, and V_{i′+1} is equal to the sum of the volume of optimized or unoptimized (i+1)-th initial solder paste and the volume of optimized or unoptimized (i+1)-th initial solder ball in the area corresponding to the compression area in the initial design structure, and V_{i′+1} is calculated by a process similar to that of V_{i′}, V_{i′+1} is known, and Hᵢ₊₁ is the height of the (i+1)-th solder ball in the compression area of the initial package structure obtained by chip warpage simulation or actual measurement, Hᵢ₊₁ is known, and thus D_{i′+1} can be obtained by empirical formula 4. It is to be noted that, in this embodiment, it is only exemplary that the diameters D_{i′} of the corresponding i-th virtual soldering ball in the optimized initial design structure and the diameters D_{i′+1} of the corresponding (i+1)-th virtual soldering ball in the optimized initial design structure are obtained by means of the empirical formula 3 and the empirical formula 4 described in the aforementioned, respectively, and in other embodiments, the diameter D_{i′} of the corresponding i-th virtual solder ball in the optimized initial design structure and the diameter D_{i′+1} of the corresponding (i+1)-th virtual solder ball in the optimized initial design structure may be obtained by means of other existing empirical formulas, respectively.

For the compression area that does not meet control rule 1, when optimization is performed in a way of reducing the volume of the initial solder balls 104 in a corresponding area on the interposer 103 (e.g., the first area 21 in FIG. 8) in the initial design structure 100, or a way of increasing the spacing distance between adjacent initial solder balls 104 in a corresponding area on the interposer 103 (e.g., the first area 21 in FIG. 9) or a combination of two or three of the aforementioned, the verification method for determining whether the control rule 1 is satisfied after optimization is similar to the verification method for determining whether the control rule 1 is satisfied after the optimization of reducing the volume of the initial solder paste 102 in a corresponding area on the package substrate 101 (e.g., the first area 21 in FIG. 7) in the initial design structure 200, and it will not be repeated herein.

When optimization is performed using optimization scheme 2 for the stretching area that does not meet control rule 2, it is also necessary to make the optimized scheme meet control rule 2, and if it does not meet control rule 2, it is necessary to further increase the volume of the initial solder paste 102 in optimization scheme 2 that is already being performed, or to further increase the volume of the solder balls 104, or to further reduce the spacing distance between adjacent solder balls 104 until the control rule 2 is met. In a specific embodiment, for example, when the optimization scheme 2 that has been performed is increasing the i-th initial solder paste 102 in a corresponding area on the package substrate 101 in the initial design structure 200 (e.g., in the second area 22 in FIG. 7) and no further optimization is performed on the volume of the solder balls 104 and the spacing distance between adjacent solder balls 104 in a corresponding area on the package substrate 101 in the initial design structure 200 (e.g., in the second area 22 in FIG. 8 and FIG. 9), after increasing the volume of the i-th initial solder paste 102 (after the optimization) in the initial design structure 200 in the corresponding area on the package substrate 101 (e.g., the second area 22 in FIG. 7), it is necessary to obtain the diameter D_{i′} of the i-th virtual solder ball and the volume V_{i′} of the i-th virtual solder ball accordingly obtained by the initial design structure after the optimization, and to substitute D_{i′} and V_{i′} into the aforementioned control rule 2 to determine or verify V_{i′}≥K₂×⅙πD_{i′}²Hᵢ, if V_{i′} is greater than or equal to K₂×⅙πD_{i′}²Hᵢ, the optimization scheme 2 that has been performed meets the control rule 2, and otherwise, the optimization scheme 2 that has been performed does not meet the control rule 1, and further adjustments need to be made to the performed optimization scheme 2, such as making the adjusted parameters further reduced or increased, or increasing the combination of optimizations (e.g., the use of one of the optimization schemes 2 described in the aforementioned turns into the use of a combination of two or three). The specific calculation process of D_{i′} and V_{i′} are described below.

The volume V_{i′} of the i-th virtual solder ball is equal to the sum of the optimized volume V_{i1′} of the i-th initial solder paste in the area corresponding to the stretching area in the initial design structure and the volume Vᵢ₂ of the corresponding unoptimized i-th initial solder ball in the initial design structure, i.e., V_{i′}=V_{i1′}+Vᵢ₂, V_{i1′} and Vᵢ₂ are obtained by the aforementioned the volume calculation formula of the solder paste and the volume calculation formula of the solder ball, respectively, and V_{i1′} and Vᵢ₂ are known, i.e., V_{i′} is known, and Hᵢ is the height of the i-th solder ball in the compression area of the initial package structure obtained by chip warpage simulation or actual measurement.

The diameter D_{i′} of the i-th virtual solder balls accordingly obtained by the optimized initial design structure is obtained by means of the empirical formula 6. The empirical formula 6 is: D_{i′}=((V_{i′}/πHᵢ− 1/12K₄Hᵢ²))^{1/2}, where K₄ is a stretching coefficient of the solder ball, V_{i′} is the volume of the i-th virtual solder ball obtained correspondingly by the optimized initial design structure, and Hᵢ is the height of the i-th solder ball in the stretching area of the initial package structure obtained by chip warpage simulation or actual measurement, and V_{i′} and Hᵢ are known, D_{i′} can be obtained by means of the empirical formula 6. It is to be noted that, in this embodiment, it is only exemplary that the diameter D_{i′} of the i-th virtual soldering ball accordingly obtained by the optimized initial design structure is obtained by the aforementioned empirical formula 6, and in other embodiments, the diameter D_{i′} of the i-th virtual soldering ball accordingly obtained by the optimized initial design structure can be obtained by other existing empirical formulas, respectively.

In the method of the present disclosure, after establishing control rule 1 and control rule 2, step 5 is firstly performed, and it is determined whether the soldering balls in the compression area of the initial package structure meet control rule 1, and whether the soldering balls in the stretching area meet control rule 2, and if they do not, then step 6 is performed, and optimization scheme 1 and optimization scheme 2 are adopted for the cases that do not meet control rule 1 and control rule 2 respectively to optimize to make them meet the control rule 1 and control rule 2, and then the subsequent step 7 is performed after optimization, the actual production of reflow soldering verification is performed, and soldering quality yield check is performed, if they are both met, then step 7 is directly performed, the subsequent step 8 is performed after step 7 to determine whether the soldering quality yield meets the design requirements, if it meets the design requirements, then it ends, if it does not meet the design requirements, then step 6-step 7 are repeated until the design requirements are met, in order to improve the problem of poor soldering (e.g., solder bridging and/or solder joint failure problems) of the chip package reflow soldering under different warpage shapes or to reduce the risk of poor soldering of the chip package reflow soldering. Moreover, in the scheme of the present disclosure, the efficiency of the optimization is improved by first performing step 5 to perform the judgment of whether the control rules are met, and the optimization in step 6 is performed only when the control rules are not met. Moreover, when optimization is performed in step 6, different optimization schemes (optimization scheme 1 and optimization scheme 1) can be used for different warpage situations (e.g., compression area or stretching area), and there are multiple ways to combine the optimization schemes, which can prevent inaccurate and excessive optimization situations from arising, and improve the accuracy of the optimization and further improve the efficiency of the optimization.

In an embodiment, when a plurality of discrete initial solder pastes 102 on the upper surface of the package substrate 101 are formed by brushing an initial solder paste material through a plurality of discrete mesh apertures in a steel mesh, the way of reducing the volume of the initial solder paste 102 in a corresponding area on the package substrate 101 in the initial design structure 100 is achieved by reducing the diameter and/or height of the mesh apertures in the steel mesh; the way of increasing the volume of the initial solder paste 102 in a corresponding area on the package substrate 101 in the initial design structure 100 is achieved by increasing the diameter and/or height of the apertures in the steel mesh.

There are some differences in the specific optimization process for the different warpage shapes of the initial package structure 200.

In a specific embodiment, referring to FIG. 6, the initial package structure 200 has warpage in the shape of a “ [symbol] ,” the initial package structure 200 comprises at least a first compression area 11 located in the middle and a first stretching area 12 located at the edge, the height Hi of the solder balls 106 in the first compression area 11 is smaller than the ideal solder ball height H, the height of the solder balls 106 in the first stretching area 12 is greater than the ideal solder ball height H; referring to FIGS. 7-9, the package substrate 101 and interposer 10 in the initial design structure 100 both have a first area 21 corresponding to the first compression area 11 and a second area 22 corresponding to the first stretching area 12; the optimization scheme 1 comprises optimizing the initial design structure 100 by using one or a combination of more of: a way of reducing the volume of the initial solder paste 102 of the first area 21 on the package substrate 101 in the initial design structure 100, a way of reducing the volume of the initial solder balls 104 of the first area 21 on the interposer 103 in the initial design structure 100, or a way of increasing the spacing distance between adjacent initial solder balls 104 of the first area 21 on the interposer 103; the optimization scheme 2 comprises optimizing the initial design structure 100 by using one or a combination of more of: a way of increasing the volume of the initial solder paste 102 in the initial design structure 100 in the second area 22 on the package substrate 101 in the initial design structure 100, a way of increasing the volume of the initial solder balls 104 in the second area 22 on the interposer 103 in the initial design structure 100, or a way of reducing the spacing distance between adjacent initial solder balls 104 in the second area 22 on the interposer 103.

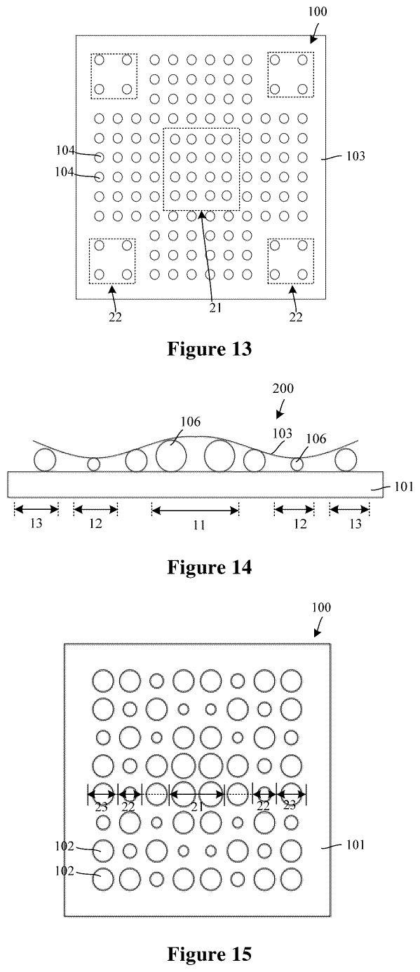

In another specific embodiment, referring to FIG. 10, the initial package structure 200 has a warpage in the shape of a “ [symbol] ,” the initial package structure 200 comprises at least a first stretching area 11 located in the middle and a first compression area 12 located at the edge, the height Hi of the solder balls 106 in the first stretching area 11 is greater than the ideal solder ball height H, the height of the solder balls 106 in the first compression area 12 is smaller than the ideal solder ball height H; referring to FIGS. 11-13, the package substrate 101 and interposer 103 of the initial design structure 100 both have a first area 21 corresponding to the first stretching area 11, and a second area 22 corresponding to the first compression area 12; the optimization scheme 1 comprises optimizing the initial design structure 100 by using one or a combination of more of: a way of reducing the volume of the initial solder paste 102 in the second area 22 on the package substrate 101 in the initial design structure 100, a way of reducing the volume of the initial solder balls 104 in the second area 22 on the interposer 103 in the initial design structure 100, or a way of increasing the spacing distance between adjacent initial solder balls 104 in the second area 22 on the interposer 103; the optimization scheme 2 comprises optimizing the initial design structure 100 by using one or a combination of more of: a way of increasing the volume of the initial solder paste 102 in the first area 21 on the package substrate 101 in the initial design structure 100, a way of increasing the volume of the initial solder balls 104 in the first area 21 on the interposer 103 in the initial design structure 100, or a way of decreasing the spacing distance between adjacent initial solder balls 104 in the first area 21 on the interposer 103.

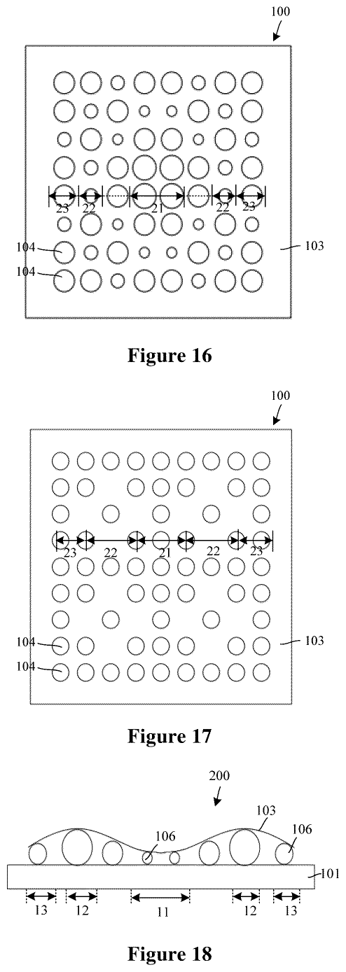

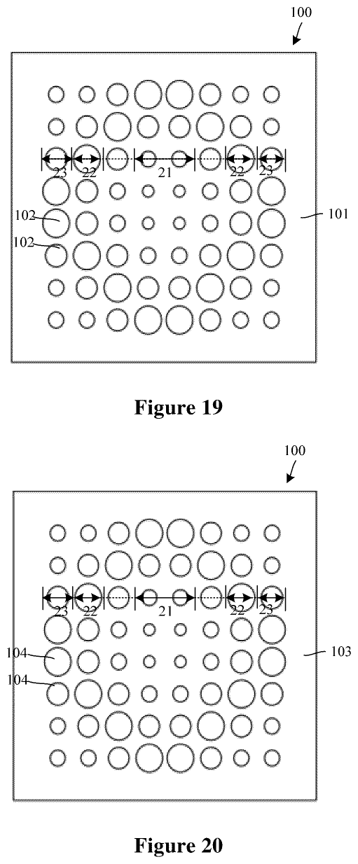

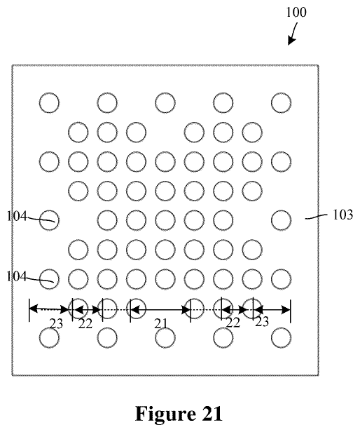

In another specific embodiment, referring to FIG. 14, the initial package structure 200 has a warpage in the shape of a “W,” the initial package structure 200 comprising at least a first stretching area 11 in the center, a first compression area 12 on both sides of the first stretching area 11, and a second stretching area 13 on the edge, the height Hi of the solder balls 106 in the first stretching area 11 and the second stretching area 13 is greater than the ideal solder ball height H, and the height Hi of the solder balls 106 in the first compression area 12 is smaller than the ideal solder ball height H; referring to FIGS. 15-17, the package substrate 101 and the interposer 103 in the initial design structure 100 both have a first area 21 corresponding to the first stretching area 11, a second area 22 corresponding to the first compression area 12, and a third area 23 corresponding to the second stretching area 13; the optimization scheme 1 comprises optimizing the initial design structure 100 by using one of or a combination of more of: a way of reducing the volume of the initial solder paste 102 in the second area 22 on the package substrate 101 in the initial design structure 100, a way of reducing the volume of the initial solder balls 104 in the second area 22 on the interposer 103 in the initial design structure 100, or a way of increasing the spacing distance between adjacent initial solder balls 104 in the second area 22 on the interposer 103; the optimization scheme 2 comprises optimizing the initial design structure 100 by using one of or a combination of more of: a way of increasing the volume of the initial solder paste 102 in the first area 21 and the third area 23 on the package substrate 101 in the initial design structure 100, a way of increasing the volume of the initial solder balls 104 in the first area 21 and the third area 23 on the interposer 103 in the initial design structure 100, or a way of reducing the spacing distance between adjacent initial solder balls 104 in the first area 21 and the third area 23 on the interposer 103.

In another specific embodiment, referring to FIG. 18, the initial package structure 200 has warpage in the shape of an “M,” the initial package structure 200 comprising at least a first compression area 11 located in the center, a first stretching area 12 located on both sides of the first compression area 11, and a second compression area 13 located at the edge, the height Hi of the solder balls 106 in the first stretching area 12 is greater than the ideal solder ball height H, and the height Hi of the solder balls 106 in the first compression area 11 and the second compression area 13 is smaller than the ideal solder ball height H; the package substrate 101 and the interposer 103 in the initial design structure 100 both have a first area 21 corresponding to the first compression area 11, a second area 22 corresponding to the first stretching area 12, and a third area 23 corresponding to the second compression area 13; the optimization scheme 1 comprises optimizing the initial design structure 100 by using one of or a combination of more of: a way of reducing the volume of the initial solder paste 102 in the first area 21 and the third area 23 on the package substrate 101 in the initial design structure 100, a way of reducing the volume of the initial solder balls 104 in the first area 21 and the third area 23 on the interposer 103 in the initial design structure 100, or a way of increasing the spacing distance between adjacent initial solder balls 104 in the first area 21 and the third area 23 on the interposer 103; the optimization scheme 2 comprises optimizing the initial design structure 100 by using one of or a combination of more of: a way of increasing the volume of the initial solder paste 102 in the second area 22 on the package substrate 101 in the initial design structure 100, a way of increasing the volume of the initial solder balls 104 in the second area 22 on the interposer 103 in the initial design structure 100, or a way of reducing the spacing distance between adjacent initial solder balls 104 in the second area 22 on the interposer 103.

Continue to refer to FIG. 1, step 7 is performed to perform actual production reflow soldering verification on the initial design structure that meets both control rule 1 and control rule 2 as well as the optimized initial design structure, and to perform soldering quality yield checks.

When step 7 is performed, reflow soldering in an actual production process is performed on the initial design structure 100 meeting both control rule 1 and control rule 2 as described in step 5 and the optimized initial design structure 100 described in step 6, and the initial solder balls 104 on the lower surface of the interposer 103 in the initial design structure 100 meeting control rule 1 and control rule 2 or the optimized initial design structure 100 are correspondingly soldered together with corresponding initial solder paste 102 on the upper surface of the package substrate 101 in the initial design structure 100 meeting control rule 1 and control rule 2 or the optimized initial design structure 100, to form a package structure to be checked, and thereafter a soldering quality yield check is performed on the package structure to be checked in order to determine whether the package structure to be checked meets the design requirements, and the contents to be checked in the soldering quality yield check comprise whether there is solder bridging between the solder balls or whether there is a great risk of solder bridging, and whether there is solder joint failure between the solder balls or whether there is a great risk of solder joint failure. The process parameters for reflow soldering in step 7 are identical to the process parameters for reflow soldering in step 2.

Continue to refer to FIG. 1, at step 8, it is determined whether the solder quality yield meets the design requirements, and if the design requirements are met, then it ends, and if the design requirements are not met, steps 6-7 are repeated until the design requirements are met.

In an embodiment, steps 6-7 are repeated, the value of K₁ in the control rule 1 can be reduced, e.g., K₁ can be reduced from an initial value to a certain value within the selection range of K₁, i.e., the reduced value of K₁ still needs to be within the selection range (50%-80%) of K₁; steps 6-7 are repeated, the value of K₂ in the control rule 2 can also be increased, e.g., K₂ can be increased from an initial value to a certain value within the selection range of K₂, i.e. K₂ still needs to be increased to a certain value within the selection range (1.1-2) of K₂, in order to further improve the efficiency and accuracy of the optimization.

In an embodiment, steps 6-7 are repeated, and it may be changed from adopting one of the optimization scheme 1 or optimization scheme 2 to adopting two or three to further improve the efficiency and accuracy of the optimization.

Although the present disclosure has been disclosed above with preferred embodiments, it is not intended to limit the present disclosure, and any person skilled in the art can make possible changes and modifications to the technical solutions of the present disclosure by utilizing the above-disclosed methods and technical contents without departing from the spirit and scope of the present disclosure, therefore, any simple modifications and equivalent changes and embellishments to the above embodiments in accordance with the technical substance of the present disclosure without departing from the technical schemes of the present disclosure fall within the protection scope of the technical solutions of the present disclosure.

What is claimed is:

1. A method for improving a reflow soldering yield of a chip package, comprising:
step 1, providing an initial design structure, the initial design structure comprising a package substrate and an interposer, an upper surface of the package substrate having a plurality of discrete initial solder pastes, a semiconductor chip being mounted to an upper surface of the interposer, and a lower surface of the interposer having a plurality of discrete initial solder balls;
step 2, performing reflow soldering on the initial design structure, soldering the initial solder balls on the lower surface of the interposer in the initial design structure together with corresponding initial solder paste on the upper surface of the package substrate in the initial design structure to form an initial package structure, and the initial solder balls and corresponding the initial solder paste are soldered together to form solder balls of the initial package structure, the initial package structure having a warpage after reflow soldering, and the initial package structure comprising at least one compression area and at least one stretching area, a height of the solder ball in the compression area being smaller than an ideal solder ball height, and the height of the solder ball in the stretching area being greater than an ideal solder ball height, the ideal solder ball height being the ideal height of the solder ball obtained by performing the soldering on the initial design structure without considering the reflow soldering warpage;
step 3, the height values of the corresponding solder balls in the compression area and in the stretching area of the initial package structure are obtained by chip warpage simulation or actual measurement, and diameters of the corresponding solder balls in the compression area and the stretching area are further obtained based on empirical formula;
step 4, based on the height values and diameters of the corresponding solder balls in the compression area and in the stretching area of the obtained initial package structure, establishing a control rule 1 for the diameters of adjacent solder balls in the compression area and a spacing distance between adjacent solder balls and a control rule 2 for a volume of the solder balls in the stretching area and the heights and diameters of the solder balls, respectively;
step 5, determining whether the solder balls in the compression area of the initial package structure meet control rule 1 and whether the solder balls in the stretching area meet control rule 2, and if no, proceeding to step 6, and if both yes, proceeding to step 7;
step 6, for the compression area that does not meet control rule 1, using optimization scheme 1 to optimize parameters of the initial solder paste and/or the initial solder balls in the area corresponding to the compression area in the initial design structure and to make them meet control rule 1; for the stretching area which does not meet control rule 2, using optimization scheme 2 to optimize the parameters of the initial solder paste and/or the initial solder balls in the area corresponding to the stretching area in the initial design structure and to make them meet control rule 2,
wherein the optimization scheme 1 comprises one of or a combination of more of: a way of reducing the volume of the initial solder paste in a corresponding area on the package substrate in the initial design structure, reducing the volume of the initial solder balls in a corresponding area on the interposer in the initial design structure, or a way of increasing the spacing distance between adjacent initial solder balls in a corresponding area on the interposer; and
the optimization scheme 2 comprises one of or a combination of more of: a way of increasing the volume of the initial solder paste in a corresponding area on the package substrate in the initial design structure, a way of increasing the volume of the initial solder balls in a corresponding area on the interposer in the initial design structure, or a way of reducing the spacing distance between adjacent initial solder balls in a corresponding area on the interposer;
step 7, performing an actual production reflow soldering verification on the initial design structure that meets both control rule 1 and control rule 2 as well as the optimized initial design structure, and performing a soldering quality yields check; and
step 8, determining whether the solder quality yield meets design requirements, and if it meets the design requirements, ending, and if it does not meet the design requirements, repeating steps 6-7 until the design requirements are met.

2. The method for improving the reflow soldering yield of a chip package according to claim 1, wherein the control rule 1 is: ½D_{ci}+½D_{ci+1}≤K₁×L_{i,i+1}, a selection range of K₁ is 50%-80%, and the initial value of K₁ can be taken as 70%, wherein D_{ci} is the diameter Dᵢ of the i-th solder ball in the compression area of the initial package structure or the diameter D_{i′} of the i-th virtual solder ball obtained by the optimized initial design structure, D_{ci+1} is the diameter Dᵢ₊₁ of the (i+1)-th solder ball in the compression area of the initial package structure or the diameter D_{i′+1} of the (i+1)-th virtual solder ball obtained by the optimized initial design structure, L_{i,i+1} is the spacing distance between the i-th initial solder ball in the area corresponding to the compression area in the initial design structure and the adjacent (i+1)-th initial solder ball or is the spacing distance between the i-th initial solder ball in the area corresponding to the compression area in the optimized initial design structure and the adjacent (i+1)-th initial solder ball.

3. The method for improving the reflow soldering yield of a chip package according to claim 2, wherein the diameter Dᵢ of the i-th solder ball in the compression area of the initial package structure and the diameter Dᵢ₊₁ of the (i+1)-th solder ball in the compression area of the initial package structure are obtained by means of the empirical formula 1 and empirical formula 2, respectively, and empirical formula 1 is: Dᵢ=((Vᵢ/πHᵢ+ 1/12K₃Hᵢ²))^{1/2}, and empirical formula 2 is: Dᵢ₊₁=((Vᵢ₊₁/πHᵢ₊₁+ 1/12K₃Hᵢ₊₁²))^{1/2}; wherein K₃ is a compression coefficient of the solder balls, Vᵢ is the volume of the i-th solder ball in the compression area of the initial package structure, and Vᵢ is equal to a sum of the volume Vᵢ₁ of the i-th initial solder paste and the volume Vᵢ₂ of the i-th initial solder ball in the area corresponding to the compression area in the initial design structure, and Hᵢ is the height of the i-th solder ball in the compression area of the initial package structure obtained by the chip warpage simulation or the actual measurement, Vᵢ₊₁ is the volume of the (i+1)-th solder ball in the compression area of the initial package structure, and Vᵢ₊₁ is equal to the sum of the volume V_{i1′} of the (i+1)-th initial solder paste and the volume V_{i2′} of the i-th initial solder ball in the area corresponding to the compression area in the initial design structure, and Hᵢ₊₁ is the height of the (i+1)-th solder ball in the compression area of the initial package structure obtained by the chip warpage simulation or the actual measurement.

4. The method for improving the reflow soldering yield of a chip package according to claim 2, wherein the diameter D_{i′} of the corresponding i-th virtual solder ball in the optimized initial design structure and the corresponding diameter D_{i′+1} of the (i+1)-th virtual solder ball in the optimized initial design structure are obtained by empirical formula 3 and empirical formula 4, respectively, empirical formula 3 is D_{i′}=((V_{i′}/πHᵢ+ 1/12K₃Hᵢ²))^{1/2} and empirical formula 4 is D_{i′+1}=((V_{i′+1}/πHᵢ₊₁+ 1/12K₃Hᵢ₊₁²))^{1/2}; wherein K3 is a compression coefficient of the solder balls, V_{i′} is the volume of the i-th virtual solder ball accordingly obtained by the optimized initial design structure, and V_{i′} is equal to the sum of the optimized or unoptimized volume of the i-th initial solder paste and the optimized or unoptimized volume of the i-th initial solder ball in the area corresponding to the compression area in the initial design structure, Hᵢ is the height of the i-th solder ball in the compression area of the initial package structure obtained by chip warpage simulation or actual measurement, V_{i′+1} is the volume of the corresponding (i+1)-th virtual solder ball in the optimized initial design structure, and V_{i′+1} is equal to the sum of the optimized or unoptimized volume of the (i+1)-th initial solder paste and the optimized or unoptimized volume of the (i+1)-th initial solder ball volume of the initial package structure in the area corresponding to the compression area in the initial design structure, and Hᵢ₊₁ is the height of the (i+1)-th solder ball in the compression area of the initial package structure obtained by chip warpage simulation or actual measurement.

5. The method for improving the reflow soldering yield of a chip package according to claim 2, wherein when repeating steps 6-7, the value of K₁ in the control rule 1 is reduced; reducing the value of K₁ in the control rule 1 comprising: reducing the K₁ from the initial value to a value within a selected range of the K₁.

6. The method for improving the reflow soldering yield of a chip package according to claim 1, wherein the control rule 2 is: V_{ci}≥K₂×⅙πD_{ci}²Hᵢ, the selection range of K₂ is 1.1-2, and the initial value of K₂ can be taken as 1.2, wherein V_{ci} is the volume Vᵢ of the i-th solder ball in the stretching area of the initial package structure or the volume V_{i′} of the i-th virtual solder ball accordingly obtained by the optimized initial design structure, D_{ci} is the diameter Dᵢ of the i-th solder ball in the compression area of the initial package structure or the diameter D_{i′} of the i-th virtual solder ball accordingly obtained by the optimized initial design structure, and Hᵢ is the height of the i-th solder ball in the compression area of the initial package structure obtained by the chip warpage simulation or the actual measurement.

7. The method for improving the reflow soldering yield of a chip package according to claim 6, wherein the diameter Dᵢ of the i-th solder ball in the stretching area of the initial package structure and the diameter D_{i′} of the i-th virtual solder ball accordingly obtained from the optimized initial design structure are obtained by means of the empirical formula 5 and the empirical formula 6, respectively, and empirical formula 5 is: Dᵢ=((Vᵢ/πHᵢ− 1/12K₄Hᵢ²))^{1/2}, and empirical formula 6 is: D_{i′}=((V_{i′}/πHᵢ− 1/12K₄Hᵢ²))^{1/2}; wherein K₄ is the stretching coefficient of the solder balls, Vᵢ is the volume of the i-th solder ball in the stretching area of the initial package structure, and Vᵢ is equal to the sum of the volume Vᵢ₁ of the i-th initial solder paste and the volume Vᵢ₂ of the i-th initial solder ball in the area corresponding to the stretching area in the initial design structure, and V_{i′} is the volume of the i-th virtual solder ball accordingly obtained by the optimized initial design structure, and Hᵢ is the height of the i-th solder ball in the stretching area of the initial package structure obtained by chip warpage simulation or actual measurement.

8. The method for improving the reflow soldering yield of a chip package according to claim 2, wherein when repeating steps 6-7, the value of K₂ in the control rule 2 is increased; increasing the value of K₂ in the control rule 2 comprises: increasing the K₂ from the initial value to a value within a selected range of the K₂.

9. The method for improving the reflow soldering yield of a chip package according to claim 1, wherein the optimization scheme 1 comprises one of or a combination of two or three of: a way of reducing the volume of the initial solder paste in a corresponding area on the package substrate in the initial design structure, reducing the volume of the initial solder balls in a corresponding area on the interposer in the initial design structure, or a way of increasing the spacing distance between adjacent initial solder balls in a corresponding area on the interposer.

10. The method for improving the reflow soldering yield of a chip package according to claim 1, wherein the optimization scheme 2 comprises one of or a combination of two or three of: a way of increasing the volume of the initial solder paste in a corresponding area on the package substrate in the initial design structure, a way of increasing the volume of the initial solder balls in a corresponding area on the interposer in the initial design structure, or a way of reducing the spacing distance between adjacent initial solder balls in a corresponding area on the interposer.

11. The method for improving the reflow soldering yield of a chip package according to claim 1, wherein in the initial design structure, volumes of the plurality of discrete initial solder pastes on the upper surface of the package substrate are the same, the volumes of the plurality of discrete initial solder balls on the lower surface of the interposer are the same, and the spacing distances between adjacent initial solder balls are the same.

12. The method for improving the reflow soldering yield of a chip package according to claim 1, wherein the warpage of the initial package structure is in a shape of a “ [symbol] ,” the initial package structure comprises at least a first compression area located in the middle and a first stretching area located at an edge, and the height of the solder ball of the first compression area is smaller than the ideal solder ball height, the height of the solder balls in the first stretching area is greater than the ideal solder ball height; the package substrate and interposer in the initial design structure both have a first area corresponding to the first compression area and a second area corresponding to the first stretching area; the optimization scheme 1 comprises optimizing the initial design structure by using one of or a combination of more of: a way of reducing the volume of the initial solder paste in the first area on the package substrate in the initial design structure, a way of reducing the volume of the initial solder balls in the first area on the interposer in the initial design structure, or a way of increasing the spacing distance between adjacent initial solder balls in the first area on the interposer; the optimization scheme 2 comprises optimizing the initial design structure by using one of or a combination of more of: a way of increasing the volume of the initial solder paste in the second area on the package substrate in the initial design structure, a way of increasing the volume of the initial solder balls in the second area on the interposer in the initial design structure, or a way of reducing the spacing distance between adjacent initial solder balls in the second area on the interposer.

13. The method for improving the reflow soldering yield of a chip package according to claim 1, wherein the warpage of the initial package structure is in the shape of a “ [symbol] ,” the initial package structure comprises at least a first stretching area located in the middle and a first compression area located at the edge, the height of the solder balls in the first stretching area is greater than the ideal solder ball height, the height of the solder balls in the first compression area is smaller than the ideal solder ball height; the package substrate and interposer in the initial design structure both have a first area corresponding to the first stretching area and a second area corresponding to the first compression area; the optimization scheme 1 comprises optimizing the initial design structure by using one of or a combination of more of: a way of reducing the volume of the initial solder paste in the second area on the package substrate in the initial design structure, a way of reducing the volume of the initial solder balls in the second area on the interposer in the initial design structure, or a way of increasing the spacing distance between adjacent initial solder balls in the second area on the interposer; the optimization scheme 2 comprises optimizing the initial design structure by using one of or a combination of more of: a way of increasing the volume of the initial solder paste in the first area on the package substrate in the initial design structure, a way of increasing the volume of the initial solder balls in the first area on the interposer in the initial design structure, or a way of reducing the spacing distance between adjacent initial solder balls in the first area on the interposer.

14. The method for improving the reflow soldering yield of a chip package according to claim 1, wherein the warpage of the initial package structure is in the shape of a “W,” the initial package structure comprises at least a first stretching area located in the middle, a first compression area located on both sides of the first stretching area, and a second stretching area located on the edge, the height of the solder balls in the first stretching area and the second stretching area is greater than the ideal solder ball height; the height of the solder balls in the first compression area is smaller than the ideal solder ball height; the package substrate and interposer in the initial design structure both have a first area corresponding to the first stretching area, a second area corresponding to the first compression area, and a third area corresponding to the second stretching area; the optimization scheme 1 comprises optimizing the initial design structure by using one of or a combination of more of: a way of reducing the volume of the initial solder paste in the second area on the package substrate in the initial design structure, a way of reducing the volume of the initial solder balls in the second area on the interposer in the initial design structure, or a way of increasing the spacing distance between adjacent initial solder balls in the second area on the interposer; the optimization scheme 2 comprises optimizing the initial design structure by using one of or a combination of more of: a way of increasing the volume of the initial solder paste in the first area and the third area on the package substrate in the initial design structure, a way of increasing the volume of the initial solder balls in the first area and the third area on the interposer in the initial design structure, or a way of reducing the spacing distance between adjacent initial solder balls in the first area and the third area on the interposer.

15. The method for improving the reflow soldering yield of a chip package according to claim 1, wherein the warpage of the initial package structure is in the shape of an “M,” the initial package structure comprises at least a first compression area located in the middle, a first stretching area located on both sides of the first compression area, and a second compression area located on the edge, the height of the solder balls in the first stretching area is greater than the ideal solder ball height; the height of the solder balls in the first compression area and the second compression area is smaller than the ideal solder ball height; the package substrate and interposer in the initial design structure both have a first area corresponding to the first compression area, a second area corresponding to the first stretching area, and a second area corresponding to the second compression area; the optimization scheme 1 comprises optimizing the initial design structure by using one of or a combination of more of: a way of reducing the volume of the initial solder paste in the first area and the second area on the package substrate in the initial design structure, a way of reducing the volume of the initial solder balls in the first area and the second area on the interposer in the initial design structure, or a way of increasing the spacing distance between adjacent initial solder balls in the first area and the second area on the interposer; the optimization scheme 2 comprises optimizing the initial design structure by using one of or a combination of more of: a way of increasing the volume of the initial solder paste in the second area on the package substrate in the initial design structure, a way of increasing the volume of the initial solder balls in the second area on the interposer in the initial design structure, or a way of reducing the spacing distance between adjacent initial solder balls in the second area on the interposer.

16. The method for improving the reflow soldering yield of a chip package according to claim 1, wherein the plurality of discrete initial solder pastes on the upper surface of the package substrate are formed by brushing an initial solder paste material into a plurality of discrete mesh apertures of a steel mesh; the way of reducing the volume of the initial solder paste in a corresponding area on the package substrate in the initial design structure is achieved by reducing the diameter and/or the height of the mesh apertures of the steel mesh; the way of increasing the volume of the initial solder paste in a corresponding area on the package substrate in the initial design structure is achieved by increasing the diameter and/or the height of the mesh apertures of the steel mesh.

17. The method for improving the reflow soldering yield of a chip package according to claim 1, wherein the package substrate is a PCB substrate or a resin substrate, and the interposer is a silicon interposer or an RDL interposer.
